(19) United States
(12) Patent Application Publication
(10) Pub. No.: US 2025/0157953 A1
(43) Pub. Date: May 15, 2025

(54) VERTICAL SEMICONDUCTOR RFID STRUCTURE, RFID TAG DEVICE, AND MANUFACTURING METHOD THEREOF

(71) Applicant: AP MEMORY TECHNOLOGY CORPORATION, HSINCHU COUNTY (TW)

(72) Inventor: WEN-LIANG CHEN, HSINCHU COUNTY (TW)

(21) Appl. No.: 18/617,412

(22) Filed: Mar. 26, 2024

Related U.S. Application Data
(60) Provisional application No. 63/598,548, filed on Nov. 14, 2023.

(51) Int. Cl. H01L 23/66; G06K 19/077; H01L 21/48; H01L 21/56; H01L 23/31; H01L 23/48

(52) U.S. Cl. CPC H01L 23/66; G06K 19/07722; H01L 21/4853; H01L 21/563; H01L 23/3185; H01L 23/481; H01L 2223/6677

(57) ABSTRACT

The present application discloses a vertical semiconductor RFID structure. The vertical semiconductor RFID structure comprises a semiconductor RFID structure, a tag IC layer, a first conductive layer, and a second conductive layer. The tag IC layer is formed on a front side of the semiconductor substrate. The first conductive layer formed over a back side of the semiconductor substrate opposite to the front side, and the second conductive layer formed over a side of the tag IC layer that is distal to the semiconductor substrate, so that the tag IC layer and the semiconductor substrate are sandwiched between the first conductive layer and the second conductive layer. The second conductive layer is electrically coupled to the tag IC layer.

### CROSS REFERENCE

This application claims the benefit of prior-filed provisional application No. 63/598,548, filed on Nov. 14, 2023, which is incorporated by reference in its entirety.

### TECHNICAL FIELD

The present disclosure relates to a semiconductor structure, and more particularly, to a vertical semiconductor radio-frequency identification (RFID) structure having conductive layers at two ends.

### DISCUSSION OF THE BACKGROUND

Radio-frequency identification (RFID) is a wireless communication technique that allows a reader to automatically identify and track tags that can be attached to objects by using electromagnetic fields. Generally, the RFID system includes an RFID reader and an RFID tag. The RFID tag can be passive and can be triggered by an electromagnetic interrogation pulse generated by a nearby RFID reader. When triggered, the RFID tag can transmit the data back to the RFID reader so that the RFID reader can complete the identification or tracking with the read data.

The RFID tag typically includes two parts: an antenna and a tag integrated circuit (IC). The antenna, which is often formed by a coil, is used to transmit and receive electromagnetic signals. The tag IC may include a logic circuit (such as a controller) for executing operations, a memory for storing data, and an analog circuit for detecting and decoding the signal received by the antenna. For a passive RFID tag, the power can be provided by RF signals sending from the RFID reader and received by the antenna. Since the passive RFID tag is feasible to be attached to a variety of products, operate without the need of power supply and allow remotely identification and tracking, it has be widely used in many applications, especially in inventory management.

### SUMMARY

One aspect of the present disclosure provides a vertical semiconductor radio frequency identification (RFID) structure. The vertical semiconductor RFID structure includes a semiconductor substrate, a tag IC layer, a first conductive layer, and a second conductive layer. The tag IC layer is formed on a front side of the semiconductor substrate. The first conductive layer is formed over a back side of the semiconductor substrate opposite to the front side. The second conductive layer is formed over a side of the tag IC layer that is distal to the semiconductor substrate, so that the tag IC layer and the semiconductor substrate are sandwiched between the first conductive layer and the second conductive layer. The second conductive layer is electrically coupled to the tag IC layer.

Another aspect of the present disclosure provides an RFID tag device. The RDIF tag device includes an antenna substrate, an antenna, and the aforementioned vertical semiconductor RFID structure coupled to the antenna. The antenna is disposed on the antenna substrate, and includes a first terminal and a second terminal. The second conductive layer, the tag IC layer, the semiconductor substrate, and the first conductive layer of the vertical semiconductor RFID structure are sequentially stacked along a first direction, and the first direction is parallel to a top surface of the antenna. From a top view, the first conductive layer overlaps the first terminal without overlapping the second terminal, and the second conductive layer overlaps the second terminal without overlapping the first terminal. The first conductive layer is electrically coupled to the first terminal, and the second conductive layer is electrically coupled to the second terminal.

Another aspect of the present disclosure provides a method for manufacturing an RFID tag device. The method includes receiving a semiconductor substrate with a tag IC layer formed on a front side of the semiconductor substrate, blanket forming a first conductive layer over a back side of the semiconductor substrate opposite to the front side, and blanket forming a second conductive layer over a side of the tag IC layer that is distal to the semiconductor substrate so that the tag IC layer and the semiconductor substrate are sandwiched between the first conductive layer and the second conductive layer. The second conductive layer, the tag IC layer, the semiconductor substrate, and the first conductive layer are sequentially stacked along a first direction, and the second conductive layer is electrically coupled to the tag IC layer. The method further includes dicing along the first direction to form a vertical semiconductor RFID structure.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows an RFID system according to one embodiment of the present disclosure.

FIG. 2 shows a structure of the RFID tag according to one comparative embodiment of the present disclosure.

FIG. 3 shows the cost analysis of the assembly flow of the RFID tag device.

FIG. 4 shows a semiconductor RFID structure according to one embodiment of the present disclosure.

FIG. 5 shows an RFID tag device according to one embodiment of the present disclosure.

FIG. 6 shows a side view of the RFID tag device in FIG. 5 according to one embodiment of the present disclosure.

FIG. 7 shows an RFID tag device according to another embodiment of the present disclosure.

FIG. 8 shows an RFID tag device according to another embodiment of the present disclosure.

FIG. 9 shows an RFID tag device according to another embodiment of the present disclosure.

FIG. 10 shows an RFID tag device according to another embodiment of the present disclosure.

FIG. 11 shows an RFID tag device according to another embodiment of the present disclosure.

FIG. 12 shows a flow chart of a method for manufacturing an RFID tag device according to one embodiment of the present disclosure.

FIGS. 13A to 13E show cross-sectional view or side view of one or more stages for manufacturing the RFID tag device in FIG. 5.

FIGS. 14A to 14B show cross-sectional view or side view of stages for attaching a semiconductor RFID structure to an antenna according to one embodiment of the present disclosure.

### DETAILED DESCRIPTION

The following description accompanies drawings, which are incorporated in and constitute a part of this specification, and which illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

Radio-Frequency Identification (RFID) systems typically include RFID readers, also known as RFID reader/writers or RFID interrogators, and RFID tags. RFID systems can be used in many ways for locating and identifying objects to which the tags are attached. RFID systems are useful in product-related and service-related industries for tracking objects being processed, inventoried, or handled. In such cases, an RFID tag is usually attached to an individual item, or to its package.

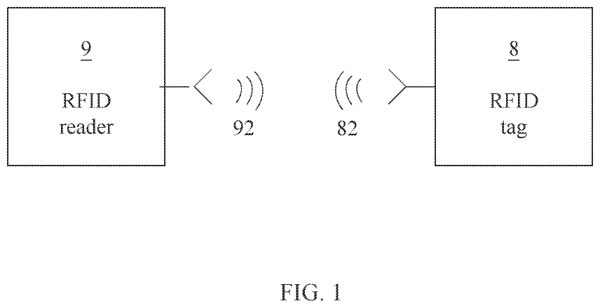

FIG. 1 shows an RFID system according to one embodiment of the present disclosure. The RFID system includes an RFID reader 9 and one or more RFID tags 8. In principle, RFID techniques entail using the RFID reader 9 to interrogate one or more RFID tags 8. The reader 9 transmitting an RF wave 92 performs the interrogation. The RF wave 92 is typically electromagnetic, at least in the far field. The RF wave 92 can also be predominantly electric or magnetic in the near field. The RF wave 92 may encode one or more commands that instruct the tags 8 to perform one or more actions.

The tag 8 that senses the interrogating RF wave 92 may respond by transmitting back another RF wave 82. The tag 8 either generates the transmitted back RF wave 82 originally, or by reflecting back a portion of the interrogating RF wave 92 in a process known as backscatter. Backscatter may take place in a number of ways.

The reflected-back RF wave 82 may encode data stored in the tag, such as a number. The response is demodulated and decoded by the reader 9, which thereby identifies, counts, or otherwise interacts with the associated item. The decoded data can denote a serial number, a price, a date, a destination, other attribute(s), any combination of attributes, and so on. Accordingly, when a reader 9 receives tag data it can learn about the item that hosts the tag 8 and/or about the tag 8 itself.

The RFID tag 8 typically includes an antenna section, a radio section, a power-management section, and frequently a logical section, a memory, or both. In some RFID tags, the power-management section included an energy storage device such as a battery. RFID tags with an energy storage device are known as battery-assisted, semi-active, or active tags. Other RFID tags can be powered solely by the RF signal they receive. Such RFID tags do not include an energy storage device and are called passive tags. Of course, even passive tags typically include temporary energy- and data/flag-storage elements such as capacitors or inductors.

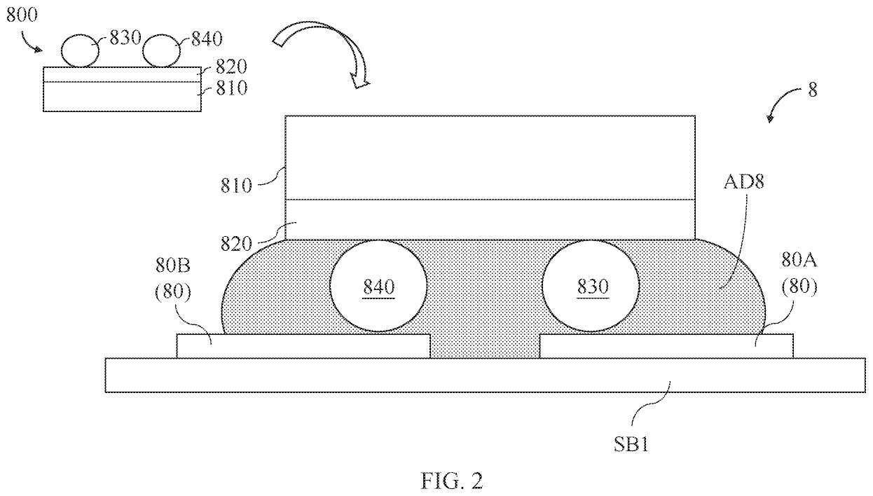

FIG. 2 shows a structure of an RFID tag device 8 according to one comparative embodiment of the present disclosure. The RFID tag device 8 includes an RFID tag integrated circuit (IC) 800 and an antenna 80. As shown in FIG. 2, the RFID tag IC 800 is flipped and attached to the antenna 80.

The RFID tag IC 800 includes a semiconductor layer 810, a tag IC layer 820, and conductive bumps 830 and 840. The semiconductor layer 810 may include a semiconductor substrate, such as a silicon substrate. The tag IC layer 820 may include circuits required for realize the functions of the RFID tag, such as a logic circuit (e.g. controller), a memory, and an analog circuit, formed therein. The conductive bumps 830 and 840 are formed on the tag IC layer 820 and coupled to the circuits formed in the tag IC layer 820 as external ports of the RFID tag IC 800. In some cases, the conductive bumps 830 and 840 can be formed by electroplating, and the conductive bumps 830 and 840 may include copper, nickel, silver, gold, or a combination thereof.

The antenna 80 may be formed by coils having specific patterns (not shown) so as to transmit and receive RF signals. The RFID tag IC 800 is coupled to the antenna 80 through the conductive bumps 830 and 840 for receiving and transmitting RF signals through the antenna 80. For example, the antenna 80 can be a dipole antenna and may include an RF terminal 80A (or as a positive signal terminal) and a ground terminal 80B (or as a negative signal terminal), and the conductive bump 830 can be coupled to RF terminal 80A while the conductive bump 840 can be coupled to the ground terminal 80B so as to receive the RF signals through the RF terminal 80A and the ground terminal 80B. In addition, an anisotropic conductive adhesive AD8 can be applied between the RFID tag IC 800 and the antenna 80 so as to adhere the RFID tag IC 800 to the antenna 80, and provide electrical connections between the conductive bump 830 and the RF terminal 80A and between the conductive bump 840 and the ground terminal 80B.

As shown in FIG. 2, since the RFID tag IC 800 is usually provided with the conductive bumps 830 and 840 facing up, the RFID tag IC 800 needs to be flipped upside down so that the RFID tag IC 800 can be attached to antenna 80 through the conductive bumps 830 and 840 during the assembly flow of the RFID tag device 8. In order to facilitate such die pick and flip-chip process, the chip area of the RFID tag IC 800 should not be too small; otherwise, the robot arm may not be able to pick up and flip the RFID tag IC 800 properly. Furthermore, another obstacle hinders the reduction of chip area of the RFID tag IC 800 is the area of the tag IC layer 820 must be large enough to accommodate the conductive bumps 830 and 840 thereon. For the technology nowadays, the chip area of the RFID tag IC 800 may not be smaller than 300 um×300 um. Therefore, the quantity of tag ICs that can be produced per wafer is rather limited.

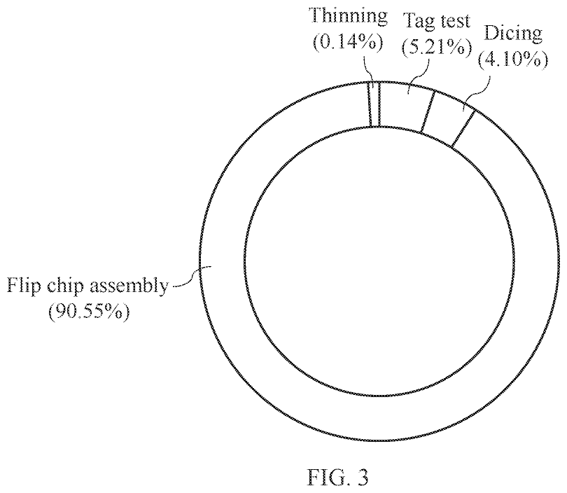

In addition, the flip-chip process can be costly. FIG. 3 shows the cost analysis of the assembly flow of an RFID tag device. According to FIG. 3, it can be noted that the cost of flip-chip assembly accounts for over 90% of the total cost. The rest of the cost mostly comes from the thinning process for thinning the thickness of the RFID tag IC 800, the dicing process and the testing process.

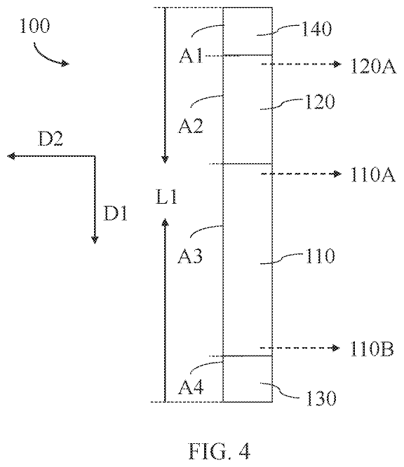

FIG. 4 shows a semiconductor RFID structure 100 according to one embodiment of the present disclosure. The semiconductor RFID structure 100 can be, for example, an RFID tag IC that can be coupled to an antenna so as to form an RFID tag. The semiconductor RFID structure 100 allows the assembly flow of the RFID tag to avoid the flip-chip process so as to reduce the manufacturing cost and break the limitation of minimum area required by the flip-chip process. As a result, a more advanced process (e.g., smaller than or equal to 45 nm technology) can be adopted so as to produce more tag ICs per wafer, thereby further reducing the manufacturing cost of the tag IC.

As shown in FIG. 4, the semiconductor RFID structure 100 includes a semiconductor substrate 110, a tag IC layer 120, a conductive layer 130, and a conductive layer 140. The tag IC layer 120 is formed on a front side 110A of the semiconductor substrate 110, and the conductive layer 130 is formed over a back side 110B of the semiconductor substrate 110, which is opposite to the front side 110A of the semiconductor substrate 110. Also, the conductive layer 140 is formed over one side 120A of the tag IC layer 120 that is distal to the semiconductor substrate 110. Consequently, the tag IC layer 120 and the semiconductor substrate 110 are sandwiched between the conductive layer 130 and the conductive layer 140.

In the present embodiment, the semiconductor RFID structure 100 has a shape of a rod. For example, the length L1 (i.e. the thickness of the semiconductor RFID structure 100 measured along the direction D1) may be longer than edges of the cross-section of the semiconductor RFID structure 100 cutting along the direction D2 that is perpendicular to the direction D1. Therefore, the semiconductor RFID structure 100 is also called a vertical semiconductor RFID structure 100.

In some embodiments, adjacent side surfaces A1, A2, A3, and A4 of the second conductive layer 140, the tag IC layer 120, the semiconductor substrate 110, and the first conductive layer 130 are parallel to the direction D1 and are cut flush.

In some embodiments, the semiconductor substrate 110 can include suitable semiconductive material such as silicon, germanium, gallium, glass, or a combination thereof. In some embodiments, the tag IC layer 120 may include devices (not shown), such as transistors and capacitors, formed in active regions at the front side 110A of the semiconductor substrate 110, and interconnect structures (not shown) used for providing routing connections between devices, so that the required circuits of the semiconductor RFID structure 100 can be formed within the tag IC layer 120. In the present embodiment, the semiconductor RFID structure 100 can be an RFID tag IC, and the tag IC layer 120 may include at least one of a logic circuit (e.g., a controller), a memory, and an analog circuit. When an RFID reader sends a request to the RFID tag, the analog circuit may detect and decode the signal received by the antenna that is coupled to the tag IC, and the controller may execute corresponding operations to retrieve the data, such as an identification number, stored in the memory, and send the data back to the RFID reader through the analog circuit and the antenna.

In some embodiments, the conductive layer 130 and the conductive layer 140 can be coupled to the tag IC layer 120 as the input/output port of the analog circuit of semiconductor RFID structure 100. In some embodiments, the conductive layer 140 can be coupled to the tag IC layer 120 through the through silicon vias (TSVs) (not shown) formed in the semiconductor substrate 110.

In some embodiments, to realize the desired connections among the devices in the tag IC layer 120, the interconnect structures may include metal lines that extend laterally at different levels and metal vias that extend vertically for connecting metal lines at different levels. In addition, the tag IC layer 120 may further include several dielectric layers stacking over each other for separating the metals lines at different levels. The dielectric layers may include dielectric material such as SiO, SiN, or doped SiO. In some embodiments, the interconnect structures and the dielectric layers may be formed in a back-end of line (BEOL), the devices may be formed in a front-end of line (FEOL), and the tag IC layer 120 may include the structures formed in both the front-end of line and the back-end of line.

In some embodiments, the conductive layers 130 and 140 may include one or more materials that provide good electrical coupling with the antenna 10. For example, the conductive layers 130 and 140 may include copper, gold, nickel, or combination thereof. In some embodiments, the conductive layers 130 and 140 may have thickness 1 um to 20 um.

In some embodiments, the conductive layers 130 and 140 may include one metal layer or multiple layers of different metals, for example, the conductive layers 130 and 140 may include a copper layer, a nickel layer and a gold layer with the gold layer disposed at an outer surface and the nickel layer sandwiched between the copper layer and the gold layer. However, the present disclosure is not limited thereto. In some embodiments, more or less metal layers may be adopted to form the conductive layers 130 and 140.

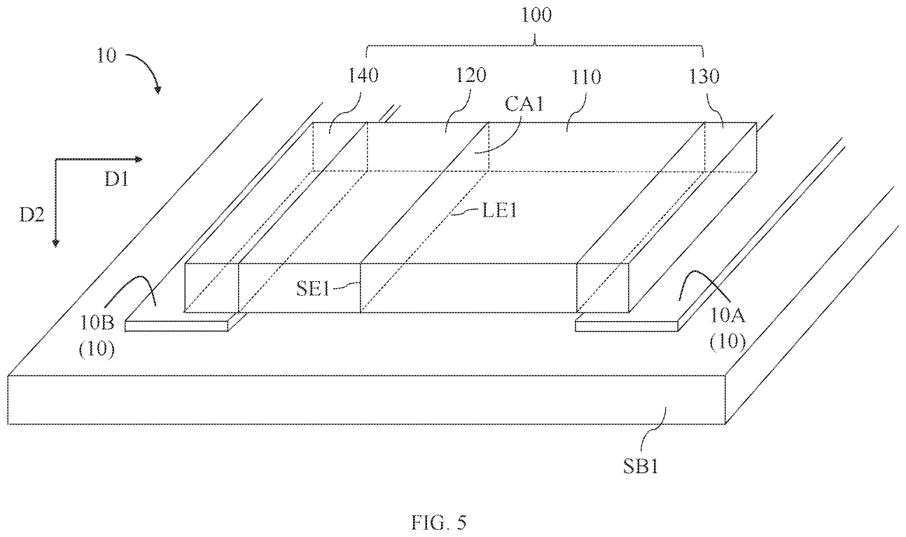

FIG. 5 shows an RFID tag device 1 according to one embodiment of the present disclosure. In some embodiments, the RFID tag device 1 can be adopted as an RFID tag, such as the RFID tag 8 shown in FIG. 1. The RFID tag device 1 includes an antenna substrate SB1, an antenna 10, and the semiconductor RFID structure 100. As shown in FIG. 5, the antenna 10 can be disposed on the antenna substrate SB.

In some embodiments, the antenna substrate SB1 can be, for example, but not limited to, a flexible substrate, such as a plastic sheet (e.g., a polyethylene terephthalate (PET) sheet or a polyvinyl toluene (PVT) sheet) or a paper. The antenna 10 can be a dipole antenna that includes a first terminal 10A and a second terminal 10B, and the semiconductor RFID structure 100 is attached to the antenna 10 so as to be coupled to the antenna 10. Specifically, from a top view, the conductive layer 130 may overlap the first terminal 10A without overlapping the second terminal 10B, and the conductive layer 140 may overlap the second terminal 10B without overlapping the first terminal 10A. In such case, the conductive layer 130 is electrically coupled to the first terminal 10A, and the conductive layer 140 is electrically coupled to the second terminal 10B. In some embodiments, the first terminal 10A and the second terminal 10B can be an RF terminal (or a positive signal terminal) and a ground terminal (or a negative signal terminal) of the antenna 10. In some embodiments, the antenna 10 may include copper, silver, aluminum, or alloy of any of the aforementioned material.

Furthermore, as shown in FIG. 5, the conductive layer 140, the tag IC layer 120, the semiconductor substrate 110, and the conductive layer 130 of the semiconductor RFID structure 100 are sequentially stacked along a first direction D1, and the first direction D1 is parallel to top surfaces of the antenna substrate SB1 and the antenna 10. In addition, the semiconductor RFID structure 100, the antenna 10 and the antenna substrate SB1 are sequentially stacked along a second direction D2, which is perpendicular to the first direction D1.

That is, unlike the RFID tag 8, which has the RFID tag IC 800 attached to the antenna 80 through the conductive bumps 830 and 840 formed on the same surface of the tag IC layer 820, the semiconductor RFID structure 100 can be attached to the antenna 10 through the conductive layers 130 and 140 at two opposite different sides of the semiconductor RFID structure 100.

In such case, during the assembly flow of the RFID tag device 1, the semiconductor RFID structure 100 can be attached to the antenna 10 by rotating about 90 degrees without requiring a flip-chip operation. As a result, the manufacturing cost of the RFID tag device 1 can be reduced significantly. Furthermore, since the flip-chip operation is eliminated from the assembly flow of the RFID tag device 1, the minimum area criteria required by the flip-chip operation no longer rules. Also, since the semiconductor RFID structure 100 can be attached to the antenna 10 with the conductive layers 130 and 140 at its two sides, the minimum chip area condition that requires for forming the conductive bumps, such as the conductive bumps 830 and 840 formed on the RFID tag IC 800, is no longer necessary, which allows more design flexibility for the semiconductor RFID structure 100. Therefore, the semiconductor RFID structure 100 can be manufactured in a much smaller size, thereby further reducing the manufacturing cost of the semiconductor RFID structure 100 and the RFID tag device 1.

As shown in FIG. 5, the semiconductor RFID structure 100 can be stacked on the antenna 10 and the antenna substrate SB1 with an extending direction (e.g., the direction D1) of the rod shape of the semiconductor RFID structure 100 parallel to the top surfaces of the antenna 10 and the antenna substrate SB1. In such case, a part of the thickness of the RFID tag device 1 that is contributed by the semiconductor RFID structure 100 can be determined by an edge length of a cross-section of the rod.

For example, a cross-section area of the semiconductor RFID structure 100, such as an interfacing area CA1 between the tag IC layer 120 and the semiconductor substrate 110 as shown in FIG. 5, is in a rectangular shape with a longer side LE1 and a shorter side SE1. In some embodiment, the longer side LE1 can be perpendicular to the second direction D2, and the shorter side SE1 can be parallel to the second direction D2. That is, the longer side LE1 may be parallel to the top surfaces of the antenna 10 and the antenna substrate SB1 while the shorter side SE1 is perpendicular to the top surfaces of the antenna 10 and the antenna substrate SB1. In such case, at least a part of the thickness of the RFID tag device 1 is determined by the length of the shorter side SE1. However, the present embodiment is not limited thereto. In some other embodiments, the longer side LE1 may be perpendicular to the top surfaces of the antenna 10 and the antenna substrate SB1 while the shorter side SE1 is parallel to the top surfaces of the antenna 10 and the antenna substrate SB1. In such case, at least a part of the thickness of the RFID tag device 1 is determined by the length of the longer side LE1. Furthermore, in some embodiments, the length L1 is greater than the longer than the shorter side SE1 and the longer side LE1, however, the present disclosure is not limited thereto.

In the embodiment shown in FIG. 5, by properly designing the layout of the tag IC layer 120, the length of the shorter side SE1 as well as a part of the thickness of the RFID tag device 1 can be determined without thinning the semiconductor substrate 110 of the semiconductor RFID structure 100. However, in some embodiments, to facilitate the step for picking up the semiconductor RFID structure 100 so as to attach the semiconductor RFID structure 100 to the antenna 10, the length of the shorter side SE1 may not be too small. In some embodiments, the length of the shorter side SE1 is about 30 um to about 300 um. Furthermore, in some embodiments, to reduce the area of the RFID tag device 1 and to facilitate the formation of TSV, the thinning process can be performed upon the semiconductor substrate 110 of the semiconductor RFID structure 100 to reduce the length L1 of the semiconductor RFID structure 100 along the first direction D1 (i.e., the stacking thickness of the semiconductor RFID structure 100). In some embodiments, the length L1 of the semiconductor RFID structure 100 is about 300 um to about 800 um depending on whether to perform the thinning process and to what degree the thinning process is performed.

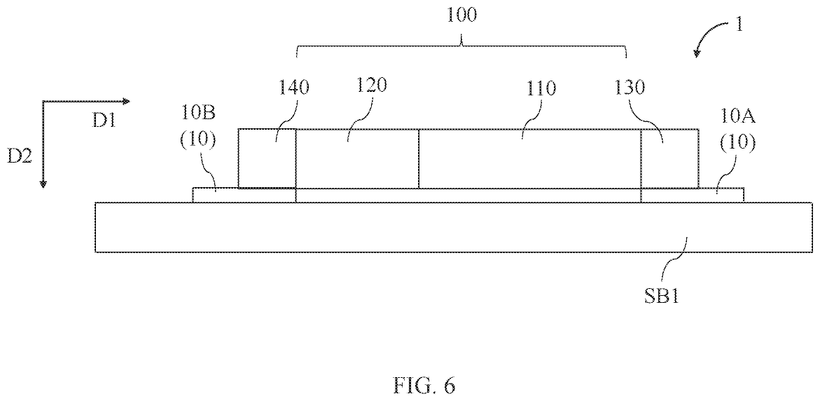

FIG. 6 shows a side view of the RFID tag device 1 according to one embodiment of the present disclosure. As shown in FIGS. 5 and 6, the conductive layer 130 can contact the first terminal 10A of the antenna 10 and the conductive layer 140 can contact the second terminal 10B of the antenna 10 directly. However, the present disclosure is not limited thereto. In some embodiments, a conductive adhesive material can be employed to adhere the conductive layers 130 and 140 to the terminals 10A and 10B of the antenna 10.

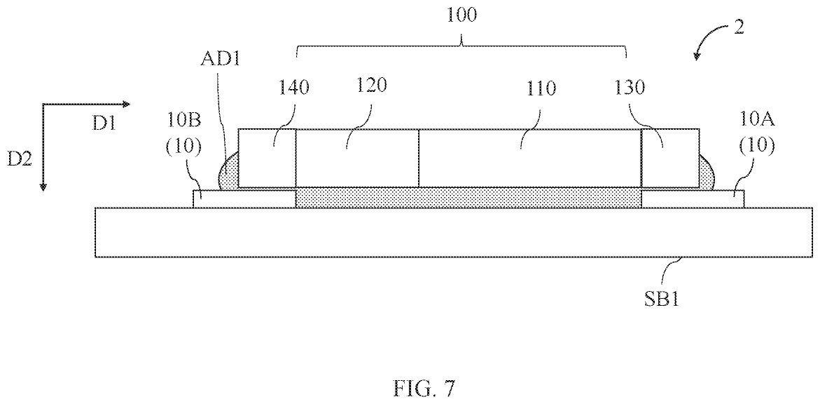

FIG. 7 shows an RFID tag device 2 according to another embodiment of the present disclosure. The RFID tag device 2 is different from the RFID tag device 1 in that the RFID tag device 2 further includes an anisotropic conductive adhesive (a.k.a., anisotropic conductive film, ACF) AD1. The anisotropic conductive adhesive AD1 is, for example, but not limited to, composed of conductive particles dispersed in a viscous resin. In the present embodiment, the anisotropic conductive adhesive AD1 is disposed between the semiconductor RFID structure 100 and the antenna 10. When heat and pressure are applied, the opposing conductive layer 130 and the first terminal 10A of the antenna 10 and the opposing conductive layer 140 and the second terminal 10B of the antenna 10 will capture the conductive particles, breaking the insulating coating of the conductive particles to establish electrical connections therein. Therefore, the anisotropic conductive adhesive AD1 can not only help to enhance the bonding between the semiconductor RFID structure 100 and the antenna 10, but also improve the conductivity between the conductive layer 130 and the first terminal 10A and the conductivity between the conductive layer 140 and the second terminal 10B.

Furthermore, the particles that are not sandwiched between conductive layer 130, 140 and the terminals 10A and 10B can be transferred within the base resin of the anisotropic conductive adhesive AD1, maintaining the insulating coating and preventing short circuits. That is, the anisotropic conductive adhesive AD1 can also improve the insulation quality along the lateral direction D1 that is perpendicular to the direction of compression so as to protect the first terminal 10A and the second terminal 10B of the antenna 10 from being short-circuited.

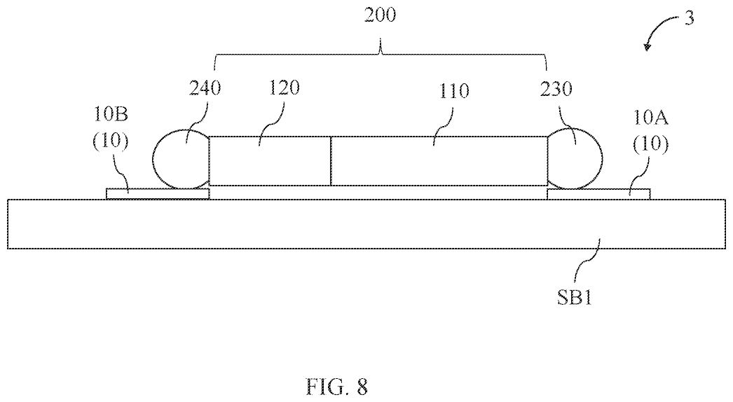

FIG. 8 shows an RFID tag device 3 according to another embodiment of the present disclosure. The RFID tag device 3 and the RFID tag device 1 are different in that the RFID tag device 3 includes a semiconductor RFID structure 200 with the conductive layers 230 and 240 formed by reflowing the conductive layers 130 and 140 so as to facilitate the assembly of the RFID tag device 3. For instance, the reflow process may be the thermal reflow process.

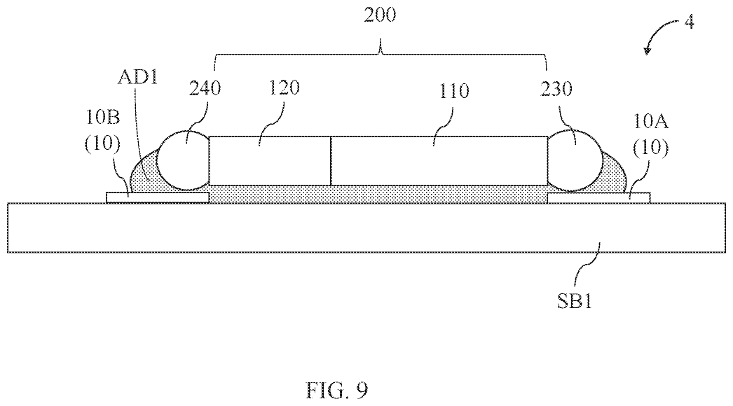

FIG. 9 shows an RFID tag device 4 according to another embodiment of the present disclosure. The difference between RFID tag device 4 and the RFID tag device 3 is in that the RFID tag 4 further includes an anisotropic conductive adhesive AD1 adhering between the semiconductor RFID structure 200 and the antenna 10 for better bonding and conductivity between the semiconductor RFID structure 200 and the antenna 10, and for better insulation between the terminals 10A and 10B of the antenna 10.

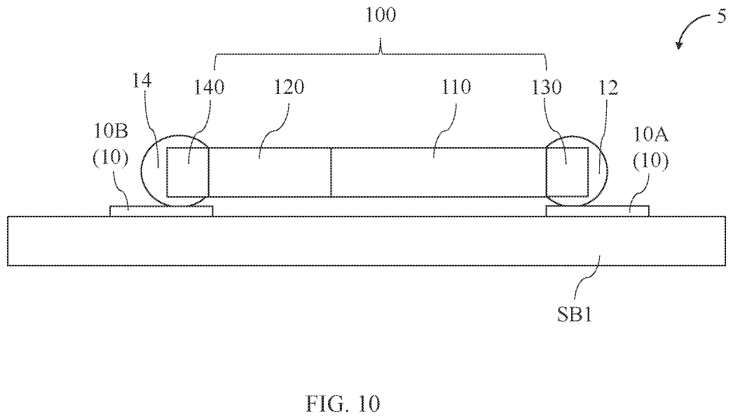

FIG. 10 shows an RFID tag device 5 according to another embodiment of the present disclosure. The RFID tag device 5 is different from the RFID tag device 1 in that the RFID tag device 5 further includes conductive contact layers 12 and 14. The conductive contact layer 12 surrounds the conductive layer 130, and is coupled between the conductive layer 130 and the first terminal 10A of the antenna 10. The conductive contact layer 14 surrounds the conductive layer 140, and is coupled between the conductive layer 140 and the second terminal 10B of the antenna 10. In some embodiments, the conductive contact layers 12 and 14 can be formed by dipping the conductive layers 130 and 140 into conductive materials, for example, but not limited to, paste of copper, gold, nickel, silver, tin or a combination thereof. However, the present disclosure is not limited thereto. In some embodiments, the conductive contact layers 12 and 14 can be formed by an electroplating process. With the conductive contact layers 12 and 14 added onto the conductive layers 130 and 140, the contact area between the conductive layer 130 and the first terminal 10A and the contact area between the conductive layer 140 and the second terminal 10B can be increased, thereby facilitating the assembly of the RFID tag device 5.

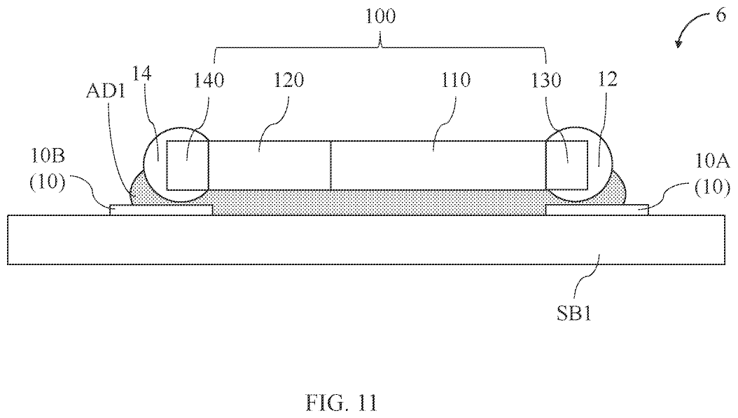

FIG. 11 shows an RFID tag device 6 according to another embodiment of the present disclosure. Compared to the RFID tag device 5, the RFID tag device 6 further includes the anisotropic conductive adhesive AD1 for adhering the metal materials 12 and 14 that surround the conductive layers 130 and 140 to the antenna 10 and the antenna substrate SB1, thereby enhancing the bonding and conductivity between the semiconductor RFID structure 100 and the antenna 10, and enhancing the insulation between the terminals 10A and 10B of the antenna 10.

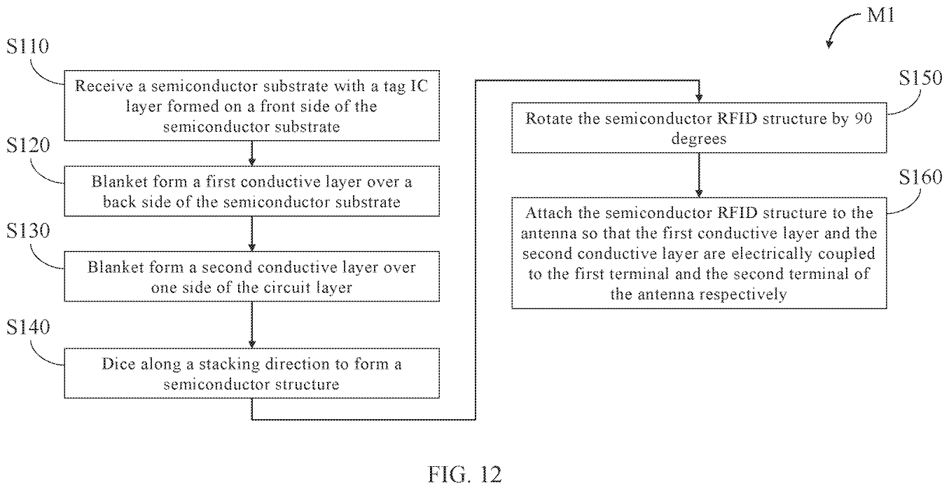

FIG. 12 shows a flow chart of a method M1 for manufacturing an RFID tag device according to one embodiment of the present disclosure. The method M1 includes steps S110 to S160 but is not limited to the performing order shown in FIG. 12. In some embodiments, the method M1 can be adopted to manufacture the RFID tag device 1.

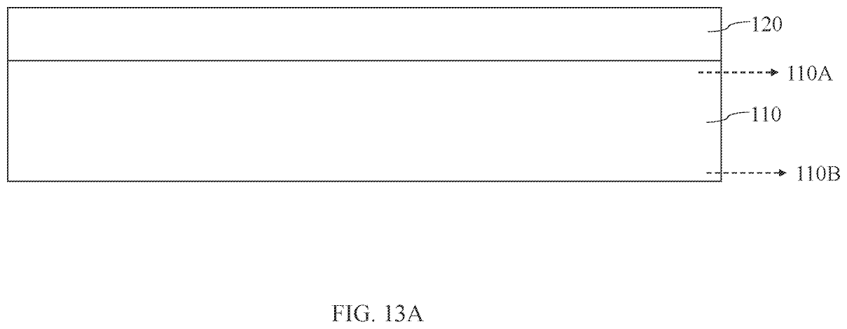

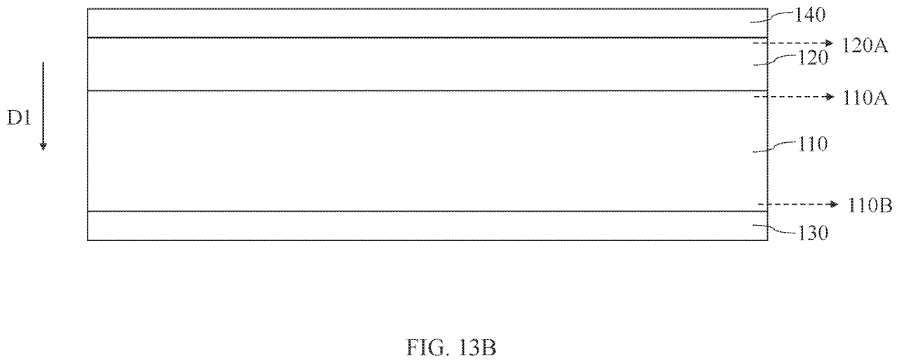

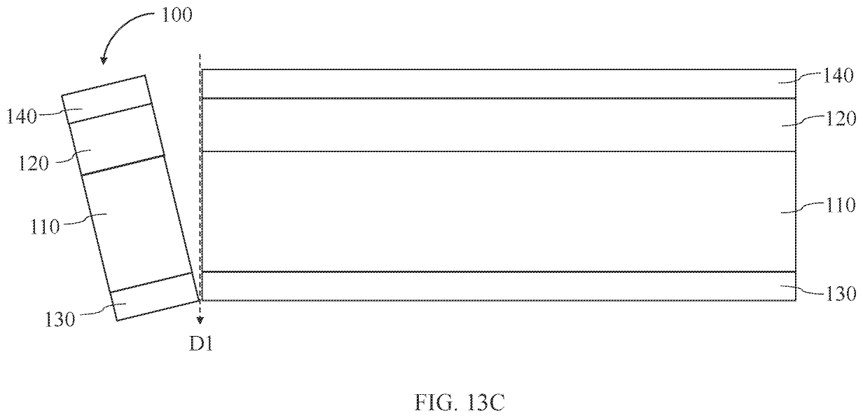

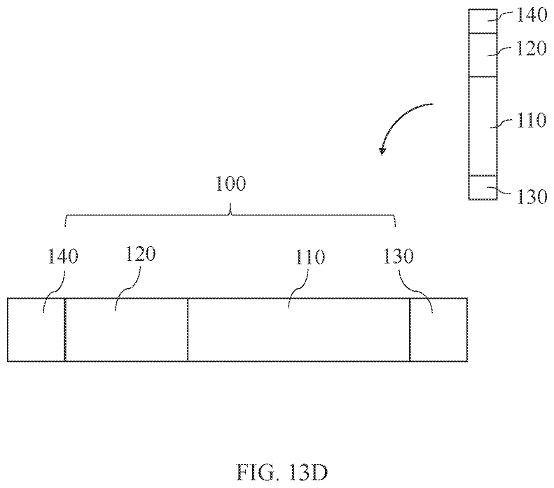

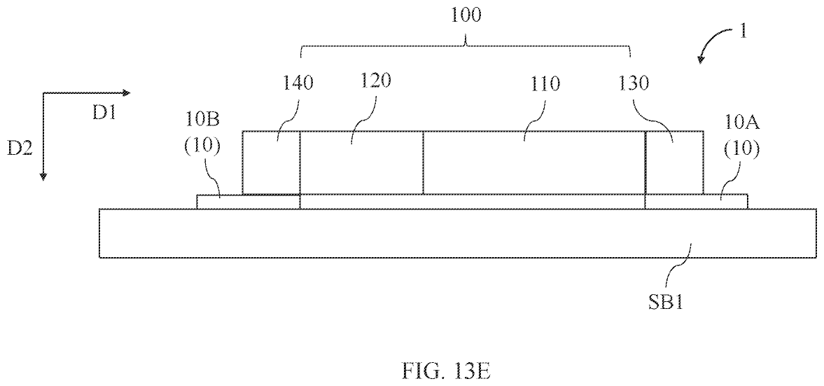

FIGS. 13A to 13E show cross-sectional view or side view of one or more stages for manufacturing the RFID tag device 1 in FIG. 6 according to the method M1.

In step S110, the semiconductor substrate 110 with the tag IC layer 120 formed on the front side 110A of the semiconductor substrate 110 is received as shown in FIG. 13A. In some embodiments, the semiconductor substrate 110 may be thinned so as to facilitate the formation of TSVs in the semiconductor substrate 110. For example, the semiconductor substrate 110 may originally have a thickness more than 700 um, and may be thinned to about 300 um. However, the present disclosure is not limited thereto. In some embodiments, the semiconductor substrate 110 may be thinned to about 100 um to further facilitate the TSV process.

In steps S120 and S130, the conductive layer 130 is formed over the back side 110B of the semiconductor substrate 110, and the conductive layer 140 is formed over the exposed side 120A of the tag IC layer 120 as shown in FIG. 13B. In some embodiments, the conductive layer 130 can be blanked deposited on the back side 110B of the semiconductor substrate 110, and the conductive layer 140 can be blanked deposited on the exposed side 120A of the tag IC layer 120.

In some embodiments, the conductive layers 130 and 140 may include the same conductive material. For example, the conductive layers 130 and 140 may include suitable metal, such as copper, gold, nickel, alloy of at least two of the aforementioned materials, or multiple-layer structure formed with at least two of the aforementioned materials. Furthermore, in some embodiments, steps S120 and S130 may be perform in a same metal depositing process, such as a chemical vapor deposition (CVD) process. However, the present disclosure is not limited thereto.

In some embodiments, steps S120 and S130 can be performed in a wafer level, and a dicing process (i.e., a sawing process) can be performed in step S140 so as to form the vertical semiconductor RFID structure 100 as shown in FIG. 13C. In some embodiments, the cutting edges of the semiconductor RFID structure 100 can be further passivated after dicing. In some embodiments, the dicing blade may cut through the second conductive layer 140, the tag IC layer 120, the semiconductor substrate 110, and the first conductive layer 130, so the adjacent side surfaces of the second conductive layer 140, the tag IC layer 120, the semiconductor substrate 110, and the first conductive layer 130 that are revealed by the cutting would be coplanar. That is, the adjacent side surfaces of the second conductive layer 140, the tag IC layer 120, the semiconductor substrate 110, and the first conductive layer 130 should be cut flush.

In some embodiments, step S140 can be performed by dicing along the direction D1 (i.e., the stacking direction of the conductive layer 140, the tag IC layer 120, the substrate 110, and the conductive layer 130), and thus, the semiconductor RFID structure 100 will have a rectangular cross section. For example, the interfacing area CA1 between the tag IC layer 120 and the semiconductor substrate 110 has a rectangular shape with a longer side LE1 and a shorter side SE1 as shown in FIG. 5.

In step S150, the antenna 10 is rotated by about 90 degrees as shown in FIG. 13D, and in step S160, the semiconductor RFID structure 100 can be attached to the antenna 10 so that the conductive layer 130 is electrically coupled to the first terminal 10A and the conductive layer 140 is electrically coupled to the second terminal 10B as shown in FIG. 13E. As a result, the stacking direction D1 of the conductive layer 140, the tag IC layer 120, the semiconductor substrate 110, and the conductive layer 130 would be perpendicular to the stacking direction of the semiconductor RFID structure 100, the antenna 10, and the antenna substrate SB1.

In addition, in some embodiments, the semiconductor RFID structure 100 can be attached to the antenna 10 with its longer side of the cross section (e.g., the longer side LE1 of the area A1 shown in FIG. 5) in parallel to the surface of the antenna substrate SB1. In such case, the shorter side of the cross section (e.g., the shorter side SE1 of the area A1 shown in FIG. 5) would contribute a part of the height of the RFID tag device 1. That is, as shown in FIG. 5, the longer side LE1 (not shown in FIG. 13E) of cross section area A1 is perpendicular to the direction D2, and the shorter side SE1 is parallel to the second direction D2. However, the present disclosure is not limited thereto.

In some embodiments, step S160 can be performed by attaching the semiconductor RFID structure 100 to the antenna 10 directly as shown in FIG. 6. However, in some embodiments, the anisotropic conductive adhesive AD1 can be adopted to improve the bonding and conductivity between the semiconductor RFID structure 100 and the antenna 10 and improve the insulation quality between the first terminal 10A and the second terminal 10B of the antenna 10 as shown in FIG. 7.

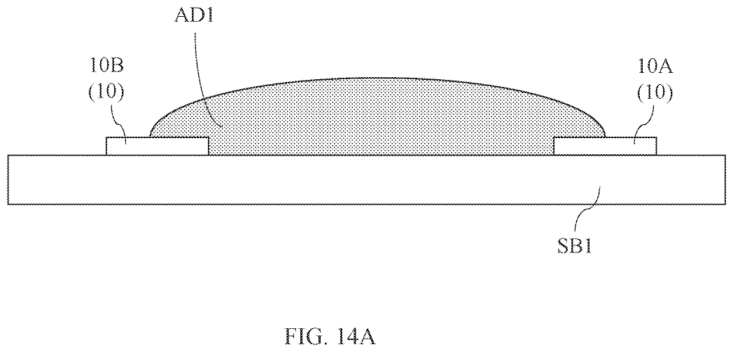

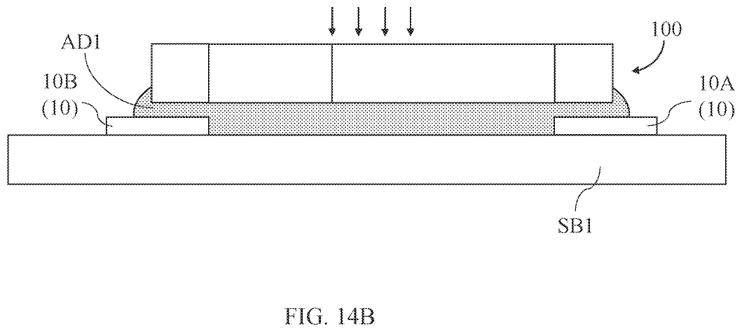

FIGS. 14A to 14B show cross-sectional view or side view of stages for attaching the semiconductor RFID structure 100 to the antenna 10 when manufacturing the RFID tag device 2 shown in FIG. 7 according to one embodiment of the present disclosure.

As shown in FIG. 14A, the anisotropic conductive adhesive AD1 can be dispensed in a viscous fluid form on the antenna substrate SB1 between the first terminal 10A and the second terminal 10B of the antenna 10 with the anisotropic conductive adhesive AD1 at least partially overlapping the first terminal 10A and the second terminal 10B of the antenna 10.

Subsequently, the semiconductor RFID structure 100 can be placed on the anisotropic conductive adhesive AD1, and a curing process can then be performed with continuous pressure and heat. By pressing the semiconductor RFID structure 100 toward the antenna 10 as shown in FIG. 14B, the conductive layer 130 and the first terminal 10A that are opposing each other would trap the conductive particles in the anisotropic conductive adhesive AD1 and breaking the insulating coating of the conductive particles, thereby establishing electrical connections between the conductive layer 130 and the first terminal 10A. Similarly, electrical connections between the opposing conductive layer 140 and the second terminal 10B can be established during the heating and pressing operations of the anisotropic conductive adhesive AD1. Consequently, by performing the processes shown in FIGS. 14A and 14B, the semiconductor RFID structure 100 can be attached to the antenna 10 with the aid of the anisotropic conductive adhesive AD1 as shown in FIG. 7.

In the present embodiment, the anisotropic conductive adhesive AD1 is able to not only adhere the semiconductor RFID structure 100 to the antenna 10 but also provide electrical connections between the conductive layer 130 and the first terminal 10A and between the conductive layer 140 and the second terminal 10B. In addition, the anisotropic conductive adhesive AD1 can further improve the insulation quality along the direction that is perpendicular to the direction of compression so as to protect the terminals 10A and 10B of the antenna 10 from being short-circuited.

In some embodiments, to further facilitate the assembly flow of the RFID tag device 1, the conductive layers 130 and 140 can be reflowed before attaching the semiconductor RFID structure 100 to the antenna 10. In such case, the conductive layers 130 and 140 will have protruding shapes, spherical shapes, droplet shapes or the like as the conductive layers 230 and 240 shown in FIG. 8. In some embodiments, the anisotropic conductive adhesive AD1 may also be applied to the conductive layers 230 and 240 for better adhesion and conductivity as shown in FIG. 9.

Alternatively, before attaching the semiconductor RFID structure 100 to the antenna 10, the method M1 may further include forming a conductive contact layer 12 surrounding the conductive layer 130 and a conductive contact layer 14 surrounding the conductive layer 140 as shown in FIG. 10. In some embodiments, the conductive contact layers 12 and 14 may include copper, gold, nickel, silver, tin, or combination thereof. In some embodiments, the conductive contact layers 12 and 14 can be formed on the conductive layers 130 and 140 by electroplating or dipping the conductive layers 130 and 140 in a conductive material. In addition, in some embodiments, the anisotropic conductive adhesive AD1 may be applied to the conductive contact layers 12 and 14 for better adhesion and conductivity as shown in FIG. 11.

In summary, the vertical semiconductor RFID structure provided by the embodiments of the present disclosure can have a rod shape with the conductive layers formed at two ends of the rod, therefore, the semiconductor RFID structure can be attached to the antenna without requiring a flip-chip operation. As a result, the manufacturing cost and the chip area of the RFID tag device can be significantly reduced.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A vertical semiconductor radio frequency identification (RFID) structure, comprising:
a semiconductor substrate;
a tag IC layer, formed on a front side of the semiconductor substrate;
a first conductive layer, formed over a back side of the semiconductor substrate opposite to the front side; and
a second conductive layer, formed over a side of the tag IC layer that is distal to the semiconductor substrate, so that the tag IC layer and the semiconductor substrate are sandwiched between the first conductive layer and the second conductive layer,
wherein the second conductive layer is electrically coupled to the tag IC layer.

2. The vertical semiconductor RFID structure of claim 1, wherein
the second conductive layer, the tag IC layer, the semiconductor substrate, and the first conductive layer are sequentially stacked along a first direction, and
adjacent side surfaces of the second conductive layer, the tag IC layer, the semiconductor substrate, and the first conductive layer are parallel to the first direction and are cut flush.

3. The vertical semiconductor RFID structure of claim 1, wherein the second conductive layer is electrically coupled to the tag IC layer through a through silicon via (TSV) formed in the semiconductor substrate.

4. The vertical semiconductor RFID structure of claim 1, wherein the second conductive layer, the tag IC layer, the semiconductor substrate, and the first conductive layer are sequentially stacked along a first direction, and a length of the vertical semiconductor RFID structure along the first direction is about 300 um to about 800 um.

5. The vertical semiconductor RFID structure of claim 1, wherein an interfacing area between the tag IC layer and the semiconductor substrate is in a rectangular shape with a longer side and a shorter side, and a length of the shorter side is about 30 um to about 300 um.

6. The vertical semiconductor RFID structure of claim 1, wherein the tag IC layer comprises at least one of a logic integrated circuit (IC), a memory IC, a power IC, or an analog IC.

7. A radio frequency identification (RFID) tag device, comprising:
an antenna substrate;
an antenna disposed on the antenna substrate, wherein the antenna comprises:
a first terminal; and
a second terminal; and
the vertical semiconductor RFID structure of claim 1, coupled to the antenna,
wherein
the second conductive layer, the tag IC layer, the semiconductor substrate, and the first conductive layer of the vertical semiconductor RFID structure are sequentially stacked along a first direction, and the first direction is parallel to a top surface of the antenna substrate;
from a top view, the first conductive layer overlaps the first terminal without overlapping the second terminal, and the second conductive layer overlaps the second terminal without overlapping the first terminal; and
the first conductive layer is electrically coupled to the first terminal, and the second conductive layer is electrically coupled to the second terminal.

8. The RFID tag device of claim 7, wherein the vertical semiconductor RFID structure, the antenna, and the antenna substrate are sequentially stacked along a second direction, and the first direction is perpendicular to the second direction.

9. The RFID tag device of claim 8, wherein an interfacing area between the tag IC layer and the semiconductor substrate is in a rectangular shape with a longer side and a shorter side, wherein the longer side is perpendicular to the second direction, and the shorter side is parallel to the second direction.

10. The RFID tag device of claim 9, wherein a length of the shorter side is about 30 um to about 300 um.

11. The RFID tag device of claim 7, wherein the first conductive layer and the second conductive layer have spherical shapes, protruding shapes or droplet shapes.

12. The RFID tag device of claim 7, further comprising:
a first conductive contact layer, surrounding the first conductive layer, and coupled between the first conductive layer and the first terminal of the antenna; and
a second conductive contact layer, surrounding the second conductive layer, and coupled between the second conductive layer and the second terminal of the antenna.

13. The RFID tag device of claim 7, further comprising an anisotropic conductive adhesive filled between the first conductive layer and the first terminal, and between the second conductive layer and the second terminal.

14. A method for manufacturing a radio frequency identification (RFID) tag device, comprising:
receiving a semiconductor substrate with a tag IC layer formed on a front side of the semiconductor substrate;
blanket forming a first conductive layer over a back side of the semiconductor substrate opposite to the front side;
blanket forming a second conductive layer over a side of the tag IC layer that is distal to the semiconductor substrate so that the tag IC layer and the semiconductor substrate are sandwiched between the first conductive layer and the second conductive layer, wherein the second conductive layer, the tag IC layer, the semiconductor substrate, and the first conductive layer are sequentially stacked along a first direction, and the second conductive layer is electrically coupled to the tag IC layer; and
dicing along the first direction to form a vertical semiconductor RFID structure.

15. The method of claim 14, further comprising:
rotating the vertical semiconductor RFID structure by 90 degrees; and
attaching the vertical semiconductor RFID structure to an antenna disposed on an antenna substrate, wherein the antenna comprises a first terminal and a second terminal, the first conductive layer is electrically coupled to the first terminal and the second conductive layer is electrically coupled to the second terminal, and the first direction is parallel to a top surface of the antenna substrate;
wherein the vertical semiconductor RFID structure, the antenna, and the antenna substrate are sequentially stacked along a second direction perpendicular to the first direction.

16. The method of claim 15, further comprising:
reflowing the first conductive layer and the second conductive layer before attaching the vertical semiconductor RFID structure to the antenna; or
forming a first conductive contact layer surrounding the first conductive layer and a second conductive contact layer surrounding the second conductive layer before attaching the vertical semiconductor RFID structure to the antenna.

17. The method of claim 15, further comprising:
dispensing an anisotropic conductive adhesive on the antenna substrate between the first terminal and the second terminal of the antenna.

18. The method of claim 14, wherein the second conductive layer is coupled to the tag IC layer through a through silicon via (TSV) formed in the semiconductor substrate.
